(19) United States
(12) Patent Application Publication
(10) Pub. No.: US 2017/0018425 A1
(43) Pub. Date: Jan. 19, 2017

(54) HETEROLEPTIC DIAZADIENYL GROUP 4 TRANSITION METAL-CONTAINING COMPOUNDS FOR VAPOR DEPOSITION OF GROUP 4 TRANSITION METAL-CONTAINING FILMS

(71) Applicant: L'Air Liquide, Société Anonyme pour I'Etude et I'Exploitation des Procédés Georges Claude, Paris (FR)

(72) Inventors: Clément LANSALOT-MATRAS, Princeton, NJ (US); Jooho LEE, Seoul (KR); Julien LIEFFRIG, Soucy (FR)

(21) Appl. No.: 15/124,427

(22) PCT Filed: Mar. 12, 2015
(86) PCT No.: PCT/IB2015/000562

§ 371 Date: Sep. 8, 2016

Related U.S. Application Data
(60) Provisional application No. 61/951,682, filed on Mar. 12, 2014.

(51) Int. Cl. H01L 21/02; H01L 27/108; C07F 7/00

(52) U.S. Cl. CPC H01L 21/02205; C07F 7/00; H01L 27/108; H01L 21/02189; H01L 21/0228; H01L 21/02274

(57) ABSTRACT

Disclosed are Group 4 transition metal-containing thin film forming precursors. Also disclosed are vapor deposition methods using the disclosed precursors to deposit Group 4 transition metal-containing thin films on one or more substrates.

### TECHNICAL FIELD

Disclosed are Group 4 transition metal-containing thin film forming precursors. Also disclosed are methods of synthesizing and using the disclosed precursors to deposit Group 4 transition metal-containing films on one or more substrates via vapor deposition processes.

### BACKGROUND

With the scaling down of semiconductor devices, new materials with high dielectric constant are required. Chemical Vapor Deposition (CVD) and Atomic Layer Deposition (ALD) have become the main deposition techniques for such thin films since CVD and ALD afford films (metal, oxide, nitride . . . etc) with a finely defined thickness and high step coverage. In CVD and ALD, the precursor molecule plays a critical role to obtain high quality films with high conformality and low impurities. That is why it is essential to develop optimum precursors. The precursor molecules require (i) high volatility to a rapid and reproducible delivery into the reaction chamber from containing vessel, (ii) high thermal stability to avoid decomposition during the storage in the canister, (iii) appropriate reactivity toward the substrate and the reacting gas to an easy conversion into the desired film, (iv) high purity and appropriate ligand design to obtain a film with low impurities.

Among high-k dielectrics, Group 4 based materials, such as HfO₂ or ZrO₂, are very promising. In addition, Group 4 metal-containing films, such as TiN, can also be used for electrode and/or Cu diffusion barrier applications.

Typical Group 4 transition metal halides have been explored for the deposition of MₓO_{y} (M=Ti, Zr, Hf; x=1; y=2) by CVD or ALD. Those precursors, mainly TiCl₄, ZrCl₄ or HfCl₄, have been widely described (See Electrochem Soc Proceedings 2005-05, 397 for HfCl₄). However, some by-products generated during the deposition process are sources of impurities which are highly detrimental to the final electrical properties, especially in the case of Cl in high-k oxide films.

Alkylamide precursors such as Hf(NMe₂)₄, Hf(NEt₂)₄ and Hf(NEtMe)₄ have been widely described in the literature (See Chem. Mater. 2002, 14, 4350; J. Appl. Phys. 2004, 43, 4129; JP2002-093804; U.S. Pat. No. 6,858,547; US 2005/0056219 A1). Some of these Group 4 alkylamide molecules are liquid at room temperature and with sufficient volatility and so suitable for ALD process. However, especially Zr alkylamide precursors have a low decomposition temperature which narrows the self-limited ALD temperature window.

New Group 4 alkylamide precursors containing a cyclopentadienyl ligand have been developed such as the one show below (Niinisto et al., Journal of Materials Chemistry (2008), 18(43), 5243-5247). These new precursors show a higher thermal stability in comparison to the tetrakis alkylamide precursors (i.e., Zr(NR₂)₄).

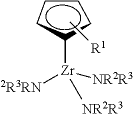

wherein R¹═H, Me, or Et; R²&R³═C₁-C₄ alkyl group

Aside from the above mentioned Group 4 metal precursors, some diazabutadiene based molecules have been developed. Diazabutadiene (DAD) ligands are α-diimine ligands that may be used under different oxidation states. The DAD ligand may be selected from one of three oxidation state forms, with each form determining the bonding mode between the center element (M) and the DAD ligands. As used herein, three different oxidation states of the ligand are described as i) neutral, ii) mono-anionic, and iii) dianionic. One of ordinary skill in the art will recognize that the location of the double bonds in the diazabutadiene ligand changes based upon the oxidation state of the ligand, as shown below:

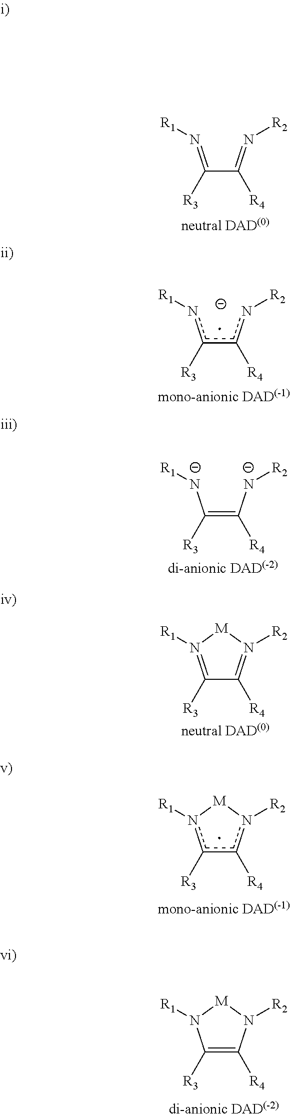

with neutral M bonds with mono-anionic M bonds with dianionic M bonds

Molecules with ethylenediamino ligand have been disclosed as CVD/ALD precursors of Group 4 metal-containing thin films (See U.S. Pat. No. 7,632,958B2)

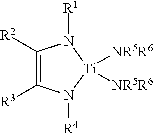

wherein R¹,R⁴═C₁-C₆ alkyl group; R²,R³═H or C₁-C₃ alkyl group; R⁵,R⁶═C₁-C₄ alkyl group

Alternatively, C. Trompke has described in her PhD dissertation (Hamburg 1992) the synthesis of heteroleptic diazadiene Group 4 compounds containing cyclopentadienyl ligand.

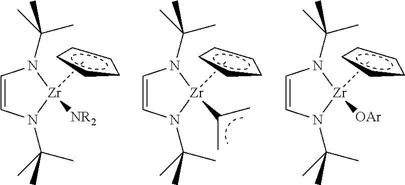

wherein R=Me, Et, TMS; Ar=2,6-bis(tert-butyl)phenolate

Among the developed molecules, some are liquid, but their thermal stability is not indicated. Even though, in the same dissertation, some PECVD of ZrO₂ using Zr(OtBu₄) or Zr(Cp)₂(OEt)₂ precursors is reported the disclosed heteroleptic diazadiene molecules have not been tested for vapor phase thin film deposition. Applicants believe that such molecules may not have sufficient vapor pressure for semiconductor applications.

A need remains for developing novel, liquid or low melting point (<50° C.), highly thermally stable, Group 4 precursor molecules suitable for vapor phase thin film deposition with controlled thickness and composition at high temperature.

### SUMMARY

Disclosed are Group 4 transition metal-containing compounds having the following formula:

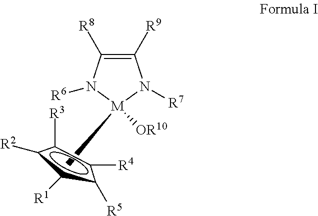

wherein M is selected from Group 4 transition metals consisting of Ti, Zr, or Hf and each R¹, R², R³, R⁴, R⁵, R⁶, R⁷, R⁸, R⁹, and R¹⁰ is independently selected from H; a C1-C5 linear, branched or cyclic alkyl group; a C1-C5 linear, branched, or cyclic alkylsilyl group (mono, bis, or tris alkyl); a C1-C5 linear, branched, or cyclic alkylamino group; or a C1-C5 linear, branched, or cyclic fluoroalkyl group. R¹, R², R³, R⁴ and R⁵ may be identical or different. R⁶ and R⁷ may be identical or different. R⁸ and R⁹ may be identical or different. The disclosed Group 4 transition metal-containing compounds may further include one or more of the following aspects:
M being Ti;
M being Zr;
M being Hf;
R¹, R², R³, R⁴ and R⁵ being independently H, Me, Et, nPr, iPr, nBu, sBu, iBu, tBu, tAmyl, F, or CF₃;
R⁶ and R⁷ being independently H, Me, Et, nPr, iPr, nBu, sBu, iBu, or tBu;
R⁸ and R⁹ being independently H, Me, Et, nPr, iPr, nBu, sBu, iBu, or tBu;
R¹⁰ being Me, Et, nPr, iPr, nBu, sBu, iBu, tBu, or tAmyl;
the Group 4 transition metal-containing compound being cyclopentadienyl(N,N-bis(tert-butyl)ethene-1,2-diaminato) (tert-butylalkoxo) Titanium(IV);
the Group 4 transition metal-containing compound being cyclopentadienyl(N,N-bis(tert-butyl)ethene-1,2-diaminato) (sec-butylalkoxo) Titanium(IV);
the Group 4 transition metal-containing compound being cyclopentadienyl(N,N-bis(tert-butyl)ethene-1,2-diaminato) (n-butylalkoxo) Titanium(IV);
the Group 4 transition metal-containing compound being cyclopentadienyl(N,N-bis(tert-butyl)ethene-1,2-diaminato) (i-butylalkoxo) Titanium(IV);
the Group 4 transition metal-containing compound being cyclopentadienyl(N,N-bis(tert-butyl)ethene-1,2-diaminato) (iso-propylalkoxo) Titanium(IV);
the Group 4 transition metal-containing compound being cyclopentadienyl(N,N-bis(tert-butyl)ethene-1,2-diaminato) (n-propylalkoxo) Titanium(IV);
the Group 4 transition metal-containing compound being cyclopentadienyl(N,N-bis(tert-butyl)ethene-1,2-diaminato) (ethylalkoxo) Titanium(IV);
the Group 4 transition metal-containing compound being cyclopentadienyl(N,N-bis(tert-butyl)ethene-1,2-diaminato) (methylalkoxo) Titanium(IV);
the Group 4 transition metal-containing compound being methylcyclopentadienyl(N,N-bis(tert-butyl)ethene-1,2-diaminato) (iso-propylalkoxo) Titanium(IV);
the Group 4 transition metal-containing compound being pentamethylcyclopentadienyl(N,N-bis(tert-butyl)ethene-1,2-diaminato) (iso-propylalkoxo) Titanium(IV);
the Group 4 transition metal-containing compound being cyclopentadienyl(N,N-bis(iso-propyl)ethene-1,2-diaminato) (iso-propylalkoxo) Titanium(IV);
the Group 4 transition metal-containing compound being (trimethylsilyl-cyclopentadienyl)(N,N-bis(tert-butyl)ethene-1,2-diaminato) (iso-propylalkoxo) Titanium(IV);
the Group 4 transition metal-containing compound being (trimethylsilyl-cyclopentadienyl)(N,N-bis(tert-butyl)ethene-1,2-diaminato) (iso-propylalkoxo) Titanium(IV);
the Group 4 transition metal-containing compound being (2, 3, 4, 5-tetramethyl-trifluoromethylcyclopentadienyl)(N,N-bis(tert-butyl)ethene-1,2-diaminato)(iso-propylalkoxo) Titanium(IV);
the Group 4 transition metal-containing compound being (cyclopentadienyl)(N,N-bis(tert-butyl)ethene-1,2-diaminato)(diethylhydroxylamine) Titanium(IV);
the Group 4 transition metal-containing compound being cyclopentadienyl(N,N-bis(tert-butyl)ethene-1,2-diaminato) (tert-butylalkoxo) Zirconium(IV);
the Group 4 transition metal-containing compound being cyclopentadienyl(N,N-bis(tert-butyl)ethene-1,2-diaminato) (sec-butylalkoxo) Zirconium(IV);
the Group 4 transition metal-containing compound being cyclopentadienyl(N,N-bis(tert-butyl)ethene-1,2-diaminato) (n-butylalkoxo) Zirconium(IV);
the Group 4 transition metal-containing compound being cyclopentadienyl(N,N-bis(tert-butyl)ethene-1,2-diaminato) (i-butylalkoxo) Zirconium(IV);
the Group 4 transition metal-containing compound being cyclopentadienyl(N,N-bis(tert-butyl)ethene-1,2-diaminato) (iso-propylalkoxo) Zirconium(IV);
the Group 4 transition metal-containing compound being cyclopentadienyl(N,N-bis(tert-butyl)ethene-1,2-diaminato) (n-propylalkoxo) Zirconium(IV);
the Group 4 transition metal-containing compound being cyclopentadienyl(N,N-bis(tert-butyl)ethene-1,2-diaminato) (ethylalkoxo) Zirconium(IV);
the Group 4 transition metal-containing compound being cyclopentadienyl(N,N-bis(tert-butyl)ethene-1,2-diaminato) (methylalkoxo) Zirconium(IV);
the Group 4 transition metal-containing compound being methylcyclopentadienyl(N,N-bis(tert-butyl)ethene-1,2-diaminato) (iso-propylalkoxo) Zirconium(IV);
the Group 4 transition metal-containing compound being pentamethylcyclopentadienyl(N,N-bis(tert-butyl)ethene-1,2-diaminato) (iso-propylalkoxo) Zirconium(IV);
the Group 4 transition metal-containing compound being cyclopentadienyl(N,N-bis(iso-propyl)ethene-1,2-diaminato) (iso-propylalkoxo) Zirconium (IV);
the Group 4 transition metal-containing compound being (trimethylsilyl-cyclopentadienyl)(N,N-bis(tert-butyl)ethene-1,2-diaminato) (iso-propylalkoxo) Zirconium (IV);
the Group 4 transition metal-containing compound being (trimethylsilyl-cyclopentadienyl)(N,N-bis(tert-butyl)ethene-1,2-diaminato) (iso-propylalkoxo) Zirconium (IV);
the Group 4 transition metal-containing compound being (2, 3, 4, 5-tetramethyl-trifluoromethylcyclopentadienyl)(N,N-bis(tert-butyl)ethene-1,2-diaminato)(iso-propylalkoxo) Zirconium (IV);
the Group 4 transition metal-containing compound being (cyclopentadienyl)(N,N-bis(tert-butyl)ethene-1,2-diaminato)(diethylhydroxylamine) Zirconium (IV);
the Group 4 transition metal-containing compound being cyclopentadienyl(N,N-bis(tert-butyl)ethene-1,2-diaminato) (tert-butylalkoxo) Hafnium(IV);
the Group 4 transition metal-containing compound being cyclopentadienyl(N,N-bis(tert-butyl)ethene-1,2-diaminato) (sec-butylalkoxo) Hafnium(IV);
the Group 4 transition metal-containing compound being cyclopentadienyl(N,N-bis(tert-butyl)ethene-1,2-diaminato) (n-butylalkoxo) Hafnium(IV);
the Group 4 transition metal-containing compound being cyclopentadienyl(N,N-bis(tert-butyl)ethene-1,2-diaminato) (i-butylalkoxo) Hafnium(IV);
the Group 4 transition metal-containing compound being cyclopentadienyl(N,N-bis(tert-butyl)ethene-1,2-diaminato) (iso-propylalkoxo) Hafnium(IV);
the Group 4 transition metal-containing compound being cyclopentadienyl(N,N-bis(tert-butyl)ethene-1,2-diaminato) (n-propylalkoxo) Hafnium(IV);
the Group 4 transition metal-containing compound being cyclopentadienyl(N,N-bis(tert-butyl)ethene-1,2-diaminato) (ethylalkoxo) Hafnium(IV);
the Group 4 transition metal-containing compound being cyclopentadienyl(N,N-bis(tert-butyl)ethene-1,2-diaminato) (methylalkoxo) Hafnium(IV);
the Group 4 transition metal-containing compound being methylcyclopentadienyl(N,N-bis(tert-butyl)ethene-1,2-diaminato) (iso-propylalkoxo) Hafnium(IV);
the Group 4 transition metal-containing compound being pentamethylcyclopentadienyl(N,N-bis(tert-butyl)ethene-1,2-diaminato) (iso-propylalkoxo) Hafnium(IV);
the Group 4 transition metal-containing compound being cyclopentadienyl(N,N-bis(iso-propyl)ethene-1,2-diaminato) (iso-propylalkoxo) Hafnium(IV);
the Group 4 transition metal-containing compound being (trimethylsilyl-cyclopentadienyl)(N,N-bis(tert-butyl)ethene-1,2-diaminato) (iso-propylalkoxo) Hafnium (IV);
the Group 4 transition metal-containing compound being (trimethylsilyl-cyclopentadienyl)(N,N-bis(tert-butyl)ethene-1,2-diaminato) (iso-propylalkoxo) Hafnium (IV);
the Group 4 transition metal-containing compound being (2, 3, 4, 5-tetramethyl-trifluoromethylcyclopentadienyl)(N,N-bis(tert-butyl)ethene-1,2-diaminato)(iso-propylalkoxo) Hafnium (IV);
the Group 4 transition metal-containing compound being (cyclopentadienyl)(N,N-bis(tert-butyl)ethene-1,2-diaminato)(diethylhydroxylamine) Hafnium (IV);

Also disclosed are Group 4 transition metal-containing thin film forming precursors having the following formula:

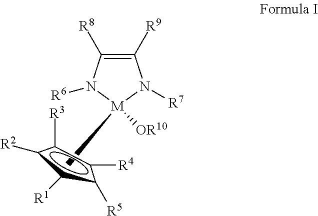

wherein M is selected from Group 4 transition metals consisting of Ti, Zr, or Hf and each R¹, R², R³, R⁴, R⁵, R⁶, R⁷, R⁸, R⁹, and R¹⁰ is independently selected from H; a C1-C5 linear, branched or cyclic alkyl group; a C1-C5 linear, branched, or cyclic alkylsilyl group (mono, bis, or tris alkyl); a C1-C5 linear, branched, or cyclic alkylamino group; or a C1-C5 linear, branched, or cyclic fluoroalkyl group. R¹, R², R³, R⁴ and R⁵ may be identical or different. R⁶ and R⁷ may be identical or different. R⁸ and R⁹ may be identical or different. The disclosed Group 4 transition metal-containing precursors may further include one or more of the following aspects:
M being Ti;
M being Zr;
M being Hf;
R¹, R², R³, R⁴ and R⁵ being independently H, Me, Et, nPr, iPr, nBu, sBu, iBu, tBu, tAmyl, F, or CF₃;
R⁶ and R⁷ being independently H, Me, Et, nPr, iPr, nBu, sBu, iBu, or tBu;
R⁸ and R⁹ being independently H, Me, Et, nPr, iPr, nBu, sBu, iBu, or tBu;
R¹⁰ being Me, Et, nPr, iPr, nBu, sBu, iBu, tBu, or tAmyl;
the Group 4 transition metal-containing thin film forming precursor being cyclopentadienyl(N,N-bis(tert-butyl)ethene-1,2-diaminato)(tert-butylalkoxo) Titanium(IV);
the Group 4 transition metal-containing thin film forming precursor being cyclopentadienyl(N,N-bis(tert-butyl)ethene-1,2-diaminato)(sec-butylalkoxo) Titanium(IV);
the Group 4 transition metal-containing thin film forming precursor being cyclopentadienyl(N,N-bis(tert-butyl)ethene-1,2-diaminato)(n-butylalkoxo) Titanium(IV);
the Group 4 transition metal-containing thin film forming precursor being cyclopentadienyl(N,N-bis(tert-butyl)ethene-1,2-diaminato)(i-butylalkoxo) Titanium(IV);
the Group 4 transition metal-containing thin film forming precursor being cyclopentadienyl(N,N-bis(tert-butyl)ethene-1,2-diaminato)(iso-propylalkoxo) Titanium(IV);
the Group 4 transition metal-containing thin film forming precursor being cyclopentadienyl(N,N-bis(tert-butyl)ethene-1,2-diaminato) (n-propylalkoxo) Titanium(IV);
the Group 4 transition metal-containing thin film forming precursor being cyclopentadienyl(N,N-bis(tert-butyl)ethene-1,2-diaminato) (ethylalkoxo) Titanium(IV);
the Group 4 transition metal-containing thin film forming precursor being cyclopentadienyl(N,N-bis(tert-butyl)ethene-1,2-diaminato) (methylalkoxo) Titanium(IV);
the Group 4 transition metal-containing thin film forming precursor being methylcyclopentadienyl(N,N-bis(tert-butyl)ethene-1,2-diaminato)(iso-propylalkoxo) Titanium(IV);
the Group 4 transition metal-containing thin film forming precursor being pentamethylcyclopentadienyl(N,N-bis(tert-butyl)ethene-1,2-diaminato)(iso-propylalkoxo) Titanium(IV);
the Group 4 transition metal-containing thin film forming precursor being cyclopentadienyl(N,N-bis(iso-propyl)ethene-1,2-diaminato)(iso-propylalkoxo) Titanium(IV);
the Group 4 transition metal-containing thin film forming precursor being (trimethylsilyl-cyclopentadienyl)(N,N-bis(tert-butyl)ethene-1,2-diaminato)(iso-propylalkoxo) Titanium(IV);
the Group 4 transition metal-containing thin film forming precursor being (trimethylsilyl-cyclopentadienyl)(N,N-bis(tert-butyl)ethene-1,2-diaminato)(iso-propylalkoxo) Titanium(IV);
the Group 4 transition metal-containing thin film forming precursor being (2, 3, 4, 5-tetramethyl-trifluoromethyl cyclopentadienyl)(N,N-bis(tert-butyl)ethene-1,2-diaminato) (iso-propylalkoxo) Titanium(IV);
the Group 4 transition metal-containing thin film forming precursor being (cyclopentadienyl)(N,N-bis(tert-butyl)ethene-1,2-diaminato)(diethylhydroxylamine) Titanium(IV);
the Group 4 transition metal-containing thin film forming precursor being cyclopentadienyl(N,N-bis(tert-butyl)ethene-1,2-diaminato)(tert-butylalkoxo) Zirconium(IV);
the Group 4 transition metal-containing thin film forming precursor being cyclopentadienyl(N,N-bis(tert-butyl)ethene-1,2-diaminato)(sec-butylalkoxo) Zirconium(IV);
the Group 4 transition metal-containing thin film forming precursor being cyclopentadienyl(N,N-bis(tert-butyl)ethene-1,2-diaminato)(n-butylalkoxo) Zirconium(IV);
the Group 4 transition metal-containing thin film forming precursor being cyclopentadienyl(N,N-bis(tert-butyl)ethene-1,2-diaminato)(i-butylalkoxo) Zirconium(IV);
the Group 4 transition metal-containing thin film forming precursor being cyclopentadienyl(N,N-bis(tert-butyl)ethene-1,2-diaminato)(iso-propylalkoxo) Zirconium(IV);
the Group 4 transition metal-containing thin film forming precursor being cyclopentadienyl(N,N-bis(tert-butyl)ethene-1,2-diaminato) (n-propylalkoxo) Zirconium(IV);
the Group 4 transition metal-containing thin film forming precursor being cyclopentadienyl(N,N-bis(tert-butyl)ethene-1,2-diaminato) (ethylalkoxo) Zirconium(IV);
the Group 4 transition metal-containing thin film forming precursor being cyclopentadienyl(N,N-bis(tert-butyl)ethene-1,2-diaminato) (methylalkoxo) Zirconium(IV);
the Group 4 transition metal-containing thin film forming precursor being methylcyclopentadienyl(N,N-bis(tert-butyl)ethene-1,2-diaminato)(iso-propylalkoxo) Zirconium(IV);
the Group 4 transition metal-containing thin film forming precursor being pentamethylcyclopentadienyl(N,N-bis(tert-butyl)ethene-1,2-diaminato)(iso-propylalkoxo) Zirconium(IV);
the Group 4 transition metal-containing thin film forming precursor being cyclopentadienyl(N,N-bis(iso-propyl)ethene-1,2-diaminato)(iso-propylalkoxo) Zirconium (IV);
the Group 4 transition metal-containing thin film forming precursor being (trimethylsilyl-cyclopentadienyl)(N,N-bis(tert-butyl)ethene-1,2-diaminato)(iso-propylalkoxo) Zirconium (IV);
the Group 4 transition metal-containing thin film forming precursor being (trimethylsilyl-cyclopentadienyl)(N,N-bis(tert-butyl)ethene-1,2-diaminato)(iso-propylalkoxo) Zirconium (IV);
the Group 4 transition metal-containing thin film forming precursor being (2, 3, 4, 5-tetramethyl-trifluoromethyl cyclopentadienyl)(N,N-bis(tert-butyl)ethene-1,2-diaminato) (iso-propylalkoxo) Zirconium (IV);
the Group 4 transition metal-containing thin film forming precursor being (cyclopentadienyl)(N,N-bis(tert-butyl)ethene-1,2-diaminato)(diethylhydroxylamine) Zirconium (IV);
the Group 4 transition metal-containing thin film forming precursor being cyclopentadienyl(N,N-bis(tert-butyl)ethene-1,2-diaminato)(tert-butylalkoxo) Hafnium(IV);
the Group 4 transition metal-containing thin film forming precursor being cyclopentadienyl(N,N-bis(tert-butyl)ethene-1,2-diaminato)(sec-butylalkoxo) Hafnium(IV);
the Group 4 transition metal-containing thin film forming precursor being cyclopentadienyl(N,N-bis(tert-butyl)ethene-1,2-diaminato)(n-butylalkoxo) Hafnium(IV);
the Group 4 transition metal-containing thin film forming precursor being cyclopentadienyl(N,N-bis(tert-butyl)ethene-1,2-diaminato)(i-butylalkoxo) Hafnium(IV);
the Group 4 transition metal-containing thin film forming precursor being cyclopentadienyl(N,N-bis(tert-butyl)ethene-1,2-diaminato)(iso-propylalkoxo) Hafnium(IV);
the Group 4 transition metal-containing thin film forming precursor being cyclopentadienyl(N,N-bis(tert-butyl)ethene-1,2-diaminato) (n-propylalkoxo) Hafnium(IV);
the Group 4 transition metal-containing thin film forming precursor being cyclopentadienyl(N,N-bis(tert-butyl)ethene-1,2-diaminato) (ethylalkoxo) Hafnium(IV);
the Group 4 transition metal-containing thin film forming precursor being cyclopentadienyl(N,N-bis(tert-butyl)ethene-1,2-diaminato) (methylalkoxo) Hafnium(IV);
the Group 4 transition metal-containing thin film forming precursor being methylcyclopentadienyl(N,N-bis(tert-butyl)ethene-1,2-diaminato)(iso-propylalkoxo) Hafnium(IV);
the Group 4 transition metal-containing thin film forming precursor being pentamethylcyclopentadienyl(N,N-bis(tert-butyl)ethene-1,2-diaminato)(iso-propylalkoxo) Hafnium(IV);
the Group 4 transition metal-containing thin film forming precursor being cyclopentadienyl(N,N-bis(iso-propyl)ethene-1,2-diaminato)(iso-propylalkoxo) Hafnium(IV);
the Group 4 transition metal-containing thin film forming precursor being (trimethylsilyl-cyclopentadienyl)(N,N-bis(tert-butyl)ethene-1,2-diaminato)(iso-propylalkoxo) Hafnium (IV);
the Group 4 transition metal-containing thin film forming precursor being (trimethylsilyl-cyclopentadienyl)(N,N-bis(tert-butyl)ethene-1,2-diaminato)(iso-propylalkoxo) Hafnium (IV);
the Group 4 transition metal-containing thin film forming precursor being (2, 3, 4, 5-tetramethyl-trifluoromethyl cyclopentadienyl)(N,N-bis(tert-butyl)ethene-1,2-diaminato) (iso-propylalkoxo) Hafnium (IV);
the Group 4 transition metal-containing thin film forming precursor being (cyclopentadienyl)(N,N-bis(tert-butyl)ethene-1,2-diaminato)(diethylhydroxylamine) Hafnium (IV);

Also disclosed are processes for the deposition of Group 4 transition metal-containing films on one or more substrates. At least one Group 4 transition metal-containing thin film forming precursors disclosed above is introduced into a reactor having at least one substrate disposed therein. At least part of the Group 4 transition metal-containing thin film forming precursor is deposited onto the at least one substrate to form the Group 4 transition metal-containing film.

The disclosed processes may further include one or more of the following aspects:
introducing at least one reactant into the reactor;
the reactant being plasma-treated;
the reactant being remote plasma-treated;
the reactant not being plasma-treated;
the reactant being selected from the group consisting of H₂, H₂CO, N₂H₄, NH₃, SiH₄, Si₂H₆, Si₃H₈, SiH₂Me₂, SiH₂Et₂, N(SiH₃)₃, hydrogen radicals thereof, and mixtures thereof;
the reactant being H₂;
the reactant being NH₃;
the reactant being selected from the group consisting of: O₂, O₃, H₂O, H₂O₂, NO, N₂O, NO₂, oxygen radicals thereof, and mixtures thereof;
the reactant being H₂O;
the reactant being plasma treated O₂;
the reactant being O₃;
the Group 4 transition metal-containing precursor and the reactant being introduced into the reactor simultaneously;
the reactor being configured for chemical vapor deposition;
the reactor being configured for plasma enhanced chemical vapor deposition;
the Group 4 transition metal-containing precursor and the reactant being introduced into the chamber sequentially;
the reactor being configured for atomic layer deposition;
the reactor being configured for plasma enhanced atomic layer deposition;
the reactor being configured for spatial atomic layer deposition;
the Group 4 transition metal-containing film being a pure Group 4 transition metal thin film;
the Group 4 transition metal-containing film being a Group 4 transition metal silicide (MₖSiₗ, wherein M is the Group 4 transition metal and each of k and l is an integer which inclusively range from 1 to 6);
the Group 4 transition metal-containing film being a Group 4 transition metal oxide (MₙOₘ, wherein M is the Group 4 transition metal and each of n and m is an integer which inclusively range from 1 to 6);
the Group 4 transition metal-containing film being TiO₂, ZrO₂ or HfO₂; and
the Group 4 transition metal-containing film being a Group 4 transition metal nitride (MₒNₚ, wherein M is the Group 4 transition metal and each of o and p is an integer which inclusively range from 1 to 6).

### Notation and Nomenclature

Certain abbreviations, symbols, and terms are used throughout the following description and claims, and include:

As used herein, the indefinite article “a” or “an” means one or more.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl; the abbreviation “Cp” refers to cyclopentadienyl; the abbreviation “Cp*” refers to pentamethylcyclopentadienyl; the abbreviation “op” refers to (open)pentadienyl; the abbreviation “DAD” refers to diazadiene and more specifically “tBuDAD” refers to N,N-bis(tert-butyl)ethene-1,2-diaminato.

The standard abbreviations of the elements from the periodic table of elements are used herein. It should be understood that elements may be referred to by these abbreviations (e.g., Mn refers to manganese, Si refers to silicon, C refers to carbon, etc.).

### BRIEF DESCRIPTION OF THE FIGURES

For a further understanding of the nature and objects of the present invention, reference should be made to the following detailed description, taken in conjunction with the accompanying figures wherein:

FIG. 1 is a ¹HNMR spectrum of Zr(Cp)(tBuDAD)(OiPr);

FIG. 2 is a ¹HNMR spectrum of Zr(Cp)(tBuDAD)(OtBu);

FIG. 3 is a ¹HNMR spectrum of Zr(Cp)(tBuDAD)(OEt);

FIG. 4 is a ¹HNMR spectrum of Zr(MeCp)(tBuDAD)(OiPr);

FIG. 5 is a ThermoGravimetric Analysis (TGA)/Differential Thermal Analysis (DTA) graph demonstrating the percentage of weight loss (TGA) or the differential temperature (DTA) with increasing temperature of Zr(Cp)(tBuDAD)(OiPr);

FIG. 6 is a TGA/DTA graph demonstrating the percentage of weight loss (TGA) or the differential temperature (DTA) with increasing temperature of Zr(Cp)(tBuDAD)(OtBu);

FIG. 7 is a TGA/DTA graph demonstrating the percentage of weight loss (TGA) or the differential temperature (DTA) with increasing temperature of Zr(Cp)(tBuDAD)(OEt);

FIG. 8 is a TGA/DTA graph demonstrating the percentage of weight loss (TGA) or the differential temperature (DTA) with increasing temperature of Zr(MeCp)(tBuDAD)(OiPr);

FIG. 9 is a graph showing the growth rates of ZrO₂ thin films using Zr(Cp)(tBuDAD)(OiPr)/O₃ as a function of the source introduction time;

FIG. 10 is a X-ray Photoelectron Spectroscopy (XPS) graph of ZrO₂ film growth using Zr(Cp)(tBuDAD)(OiPr);

FIG. 11 is a X-rays diffraction spectrum of a ZrO₂ film growth using Zr(Cp)(tBuDAD)(OiPr) at 300° C.;

FIG. 12 is a graph showing the growth rates of ZrO₂ thin films using Zr(MeCp)(tBuDAD)(OiPr)/O₃ as a function of the source introduction time;

FIG. 13 is a X-ray Photoelectron Spectroscopy (XPS) graph of ZrO₂ film growth using Zr(MeCp)(tBuDAD)(OiPr); and

FIG. 14 is a X-rays diffraction spectrum of a ZrO₂ film growth using Zr(MeCp)(tBuDAD)(OiPr) at 325° C.

### DESCRIPTION OF PREFERRED EMBODIMENTS

Disclosed are Group 4 transition metal-containing compounds having the following formula:

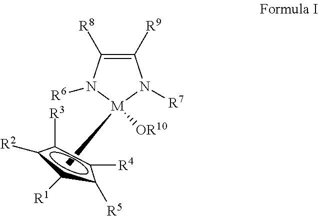

wherein M is selected from Group 4 transition metals consisting of Ti, Zr, or Hf and each R¹, R², R³, R⁴, R⁵, R⁶, R⁷, R⁸, R⁹, and R¹⁰ is independently selected from H; a C1-C5 linear, branched or cyclic alkyl group; a C1-C5 linear, branched, or cyclic alkylsilyl group (mono, bis, or tris alkyl); a C1-C5 linear, branched, or cyclic alkylamino group; or a C1-C5 linear, branched, or cyclic fluoroalkyl group. R¹, R², R³, R⁴ and R⁵ may be identical or different. R⁶ and R⁷ may be identical or different, R⁸ and R⁹ may be identical or different. Each R¹, R², R³, R⁴ and R⁵ may independently be H, Me, Et, nPr, iPr, nBu, sBu, iBu, tBu, tAmyl, F, or CF₃. Each R⁶ and R⁷ may independently be H, Me, Et, nPr, iPr, nBu, sBu, iBu, or tBu. Each R⁸ and R⁹ may independently be H, Me, Et, nPr, iPr, nBu, sBu, iBu, or tBu. R¹⁰ may be Me. Et, nPr, iPr, nBu, sBu, Bu, tBu, or tAmyl.

Preferably R⁶ and R⁷ are tBu because bulky tertiary alkyl groups may help stabilize the diazadiene group. Preferably R⁸ and R⁹ are H because small groups may increase the volatility of the metal-containing compound. Preferably R¹⁰ is iPr because smaller alkyl groups may increase the volatility and decrease the melting point of the metal-containing compound.

Exemplary Ti-containing compounds include but are not limited to cyclopentadienyl(N, N-bis(tert-butyl)ethene-1,2-diaminato)(tert-butylalkoxo) Titanium(IV); cyclopentadienyl(N,N-bis(tert-butyl)ethene-1,2-diaminato) (sec-butylalkoxo) Titanium(IV); cyclopentadienyl(N,N-bis(tert-butyl)ethene-1,2-dieminato)(n-butylalkoxo) Titanium(IV); cyclopentadienyl(N,N-bis(tert-butyl)ethene-1,2-diaminato)(i-butylalkoxo) Titanium(IV); cyclopentadienyl(N,N-bis(tert-butyl)ethene-1,2-diaminato)(iso-propylalkoxo) Titanium(IV); cyclopentadienyl(N, N-bis(tert-butyl)ethene-1,2-diaminato) (n-propylalkoxo) Titanium(IV); cyclopentadienyl(N,N-bis(tert-butyl)ethene-1,2-diaminato)(ethylalkoxo) Titanium(IV); cyclopentadienyl(N,N-bis(tert-butyl)ethene-1,2-diaminato)(methylalkoxo) Titanium(IV); methylcyclopentadienyl(N,N-bis(tert-butyl)ethene-1,2-diaminato)(iso-propylalkoxo) Titanium(IV); pentamethylcyclopentadienyl(N, N-bis(tert-butyl)ethene-1,2-diaminato)(iso-propylalkoxo) Titanium(IV); cyclopentadienyl(N,N-bis(iso-propyl)ethene-1,2-diaminato)(iso-propylalkoxo) Titanium(IV); (trimethylsilyl-cyclopentadienyl)(N,N-bis(tert-butyl)ethene-1,2-diaminato)(iso-propylalkoxo) Titanium(IV); (trimethylsilyl-cyclopentadienyl)(N,N-bis(tert-butyl)ethene-1,2-diaminato)(iso-propylalkoxo) Titanium(IV); (2, 3, 4, 5-tetramethyl-trifluoromethylcyclopentadienyl)(N,N-bis(tert-butyl)ethene-1,2-diaminato)(iso-propylalkoxo) Titanium(IV); and (cyclopentadienyl)(N,N-bis(tert-butyl)ethene-1,2-diaminato)(diethylhydroxylamine) Titanium(IV).

Exemplary Zr-containing compounds include but are not limited to cyclopentadienyl(N,N-bis(tert-butyl)ethene-1,2-diaminato) (tert-butylalkoxo) Zirconium(IV); cyclopentadienyl(N,N-bis(tert-butyl)ethene-1,2-diaminato)(sec-butylalkoxo) Zirconium(IV); cyclopentadienyl(N,N-bis(tert-butyl)ethene-1,2-diaminato) (n-butylalkoxo) Zirconium(IV); cyclopentadienyl(N,N-bis(tert-butyl)ethene-1,2-diaminato)(i-butylalkoxo) Zirconium(IV); cyclopentadienyl(N,N-bis(tert-butyl)ethene-1,2-diaminato)(iso-propylalkoxo) Zirconium(IV); cyclopentadienyl(N, N-bis(tert-butyl)ethene-1,2-diaminato)(n-propylalkoxo) Zirconium(IV); cyclopentadienyl(N,N-bis(tert-butyl)ethene-1,2-diaminato) (ethylalkoxo) Zirconium(IV); cyclopentadienyl(N,N-bis(tert-butyl)ethene-1,2-diaminato)(methylalkoxo) Zirconium(IV); methylcyclopentadienyl(N,N-bis(tert-butyl)ethene-1,2-diaminato) (iso-propylalkoxo) Zirconium(IV); pentamethylcyclopentadienyl(N, N-bis(tert-butyl)ethene-1,2-diaminato)(iso-propylalkoxo) Zirconium(IV); cyclopentadienyl(N,N-bis(iso-propyl)ethene-1,2-diaminato)(iso-propylalkoxo) Zirconium (IV); (trimethylsilyl-cyclopentadienyl)(N,N-bis(tert-butyl)ethene-1,2-diaminato)(iso-propylalkoxo) Zirconium (IV); (trimethylsilyl-cyclopentadienyl)(N, N-bis(tert-butyl)ethene-1,2-diaminato)(iso-propylalkoxo) Zirconium (IV); (2, 3, 4, 5-tetramethyl-trifluoromethylcyclopentadienyl)(N,N-bis(tert-butyl)ethene-1,2-diaminato)(iso-propylalkoxo) Zirconium (IV); and (cyclopentadienyl)(N,N-bis(tert-butyl)ethene-1,2-diaminato) (diethylhydroxylamine) Zirconium (IV).

Exemplary Hf-containing compounds include but are not limited to cyclopentadienyl(N,N-bis(tert-butyl)ethene-1,2-diaminato) (tert-butylalkoxo) Hafnium(IV); cyclopentadienyl(N,N-bis(tert-butyl)ethene-1,2-diaminato) (sec-butylalkoxo) Hafnium(IV); cyclopentadienyl(N,N-bis(tert-butyl)ethene-1,2-diaminato) (n-butylalkoxo) Hafnium(IV); cyclopentadienyl(N,N-bis(tert-butyl)ethene-1,2-diaminato)(i-butylalkoxo) Hafnium(IV); cyclopentadienyl(N,N-bis(tert-butyl)ethene-1,2-diaminato) (iso-propylalkoxo) Hafnium(IV); cyclopentadienyl(N, N-bis(tert-butyl)ethene-1,2-diaminato)(n-propylalkoxo) Hafnium(IV); cyclopentadienyl(N,N-bis(tert-butyl)ethene-1,2-diaminato) (ethylalkoxo) Hafnium(IV); cyclopentadienyl(N,N-bis(tert-butyl)ethene-1,2-diaminato)(methylalkoxo) Hafnium(IV); methylcyclopentadienyl(N,N-bis(tert-butyl)ethene-1,2-diaminato) (iso-propylalkoxo) Hafnium(IV); pentamethylcyclopentadienyl(N, N-bis(tert-butyl)ethene-1,2-diaminato)(iso-propylalkoxo) Hafnium(IV); cyclopentadienyl(N,N-bis(iso-propyl)ethene-1,2-diaminato)(iso-propylalkoxo) Hafnium(IV); (trimethylsilyl-cyclopentadienyl)(N,N-bis(tert-butyl)ethene-1,2-diaminato)(iso-propylalkoxo) Hafnium (IV); (trimethylsilyl-cyclopentadienyl)(N,N-bis(tert-butyl)ethene-1,2-diaminato)(iso-propylalkoxo) Hafnium (IV); (2, 3, 4, 5-tetramethyl-trifluoromethylcyclopentadienyl)(N,N-bis(tert-butyl)ethene-1,2-diaminato)(iso-propylalkoxo) Hafnium (IV); and (cyclopentadienyl)(N,N-bis(tert-butyl)ethene-1,2-diaminato) (diethylhydroxylamine) Hafnium (IV).

Preferably, the Group 4 transition metal-containing compound is cyclopentadienyl(N, N-bis(tert-butyl)ethene-1,2-diaminato)mono(iso-propylalkoxo) Zirconium(IV) or methylcyclopentadienyl(N,N-bis(tert-butyl)ethene-1,2-diaminato) mono(iso-propylalkoxo) Zirconium(IV), due to its excellent vaporization results in atmospheric thermo gravimetric analysis, leaving a small amount of final residue.

The disclosed Group 4 transition metal-containing compounds may be synthesized by reacting the corresponding lithium alkoxide or lithium amide with the corresponding cyclopentadienyl diazadiene chloride Group 4 transition metal in a suitable solvent, such as THF and ether, at low temperature. The cyclopentadienyl diazadiene chloride Group 4 transition metal compound itself may be prepared by reacting the commercial cyclopentadienyl tri-chloride Group 4 transition metal compound with di-lithium diazadienyl, which is freshly prepared from diazadiene and two equivalents of metal Lithium in a suitable solvent, such as THF and ether, at low temperature. Alternatively the specific cyclopentadienyl diazadiene alkoxy Group 4 transition metal-containing compound may be synthesized by alcoholysis of the corresponding cyclopentadienyl diazadiene amino Group 4 transition metal-containing compound using the corresponding alcohol in a suitable solvent, such as THF and ether, at low temperature. Exemplary synthesis methods containing further details are provided in the Examples that follow.

Purity of the disclosed Group 4 transition metal-containing compound is preferably higher than 99.9% w/w. Disclosed Group 4 transition metal-containing compounds may contain any of the following impurities: cyclopentadiene, alkylamines, dialkylamines, THF, ether, toluene, chlorinated metal compounds, di-lithium diazadienyl, lithium alkoxy, lithium amide. Preferably, the total quantity of these impurities is below 0.1% w/w.

The disclosed Group 4 transition metal-containing compound may also include metal impurities at the ppbw (part per billion weight) level. These metal impurities include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), Vanadium (V) and Zinc (Zn).

Also disclosed are methods for forming Group 4 transition metal-containing layers on a substrate using a vapor deposition process. The method may be useful in the manufacture of semiconductor, photovoltaic, LCD-TFT, or flat panel type devices. The disclosed Group 4 transition metal-containing compounds may be used to deposit thin Group 4 transition metal-containing films using any deposition methods known to those of skill in the art. Examples of suitable deposition methods include without limitation, conventional chemical vapor deposition (CVD), atomic layer deposition (ALD), or other types of depositions that are related to vapor coating such as a plasma enhanced CVD (PECVD), plasma enhanced ALD (PEALD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), spatial ALD, hot-wire ALD (HWALD), radicals incorporated deposition, and super critical fluid deposition or combinations thereof. The deposition method is preferably ALD, PE-ALD, or spatial ALD in order to provide suitable step coverage and film thickness control.

The disclosed Group 4 transition metal-containing compounds may be supplied either in neat form or in a blend with a suitable solvent, such as ethyl benzene, xylene, mesitylene, decane, dodecane. The disclosed compounds may be present in varying concentrations in the solvent.

One or more of the neat or blended Group 4 transition metal-containing compounds are introduced into a reactor in vapor form by conventional means, such as tubing and/or flow meters. The compound in vapor form may be produced by vaporizing the neat or blended compound solution through a conventional vaporization step such as direct vaporization, distillation, or by bubbling, or by using a sublimator such as the one disclosed in PCT Publication WO2009/087609 to Xu et al. The neat or blended compound may be fed in liquid state to a vaporizer where it is vaporized before it is introduced into the reactor. Alternatively, the neat or blended compound may be vaporized by passing a carrier gas into a container containing the compound or by bubbling the carrier gas into the compound. The carrier gas may include, but is not limited to, Ar, He, N₂, and mixtures thereof. Bubbling with a carrier gas may also remove any dissolved oxygen present in the neat or blended compound solution. The carrier gas and compound are then introduced into the reactor as a vapor.

If necessary, the container of disclosed compound may be heated to a temperature that permits the compound to be in its liquid phase and to have a sufficient vapor pressure. The container may be maintained at temperatures in the range of, for example, approximately 0° C. to approximately 150° C. Those skilled in the art recognize that the temperature of the container may be adjusted in a known manner to control the amount of compound vaporized.

The reactor may be any enclosure or chamber within a device in which deposition methods take place such as without limitation, a parallel-plate type reactor, a cold-wall type reactor, a hot-wall type reactor, a single-wafer reactor, a multi-wafer reactor, or other types of deposition systems under conditions suitable to cause the compounds to react and form the layers.

Generally, the reactor contains one or more substrates onto which the thin films will be deposited. The substrates may be any suitable substrate used in semiconductor, photovoltaic, flat panel, or LCD-TFT device manufacturing. Examples of suitable substrates include without limitation, silicon substrates, silica substrates, silicon nitride substrates, silicon oxy nitride substrates, tungsten substrates, or combinations thereof. Additionally, substrates comprising tungsten or noble metals (e.g. platinum, palladium, rhodium, or gold) may be used. Plastic substrates, such as poly(3,4-ethylenedioxythiophene)poly (styrenesulfonte) [PEDOT:PSS], may also be used. The substrate may also have one or more layers of differing materials already deposited upon it from a previous manufacturing step. For example, a ZrO₂ film may be deposited onto a TiN substrate. In subsequent processing, a TiN layer may be deposited on the ZrO₂ layer, forming a TiN/ZrO₂/TiN stack used as DRAM capacitor.

The temperature and the pressure within the reactor are held at conditions suitable for vapor depositions. In other words, after introduction of the vaporized compound into the chamber, conditions within the chamber are such that at least part of the vaporized compound is deposited onto the substrate to form a Group 4 transition metal-containing film. For instance, the pressure in the reactor may be held between about 1 Pa and about 10⁵ Pa, more preferably between about 25 Pa and about 10³ Pa, as required per the deposition parameters. Likewise, the temperature in the reactor may be held between about 100° C. and about 500° C., preferably between about 150° C. and about 400° C. One of ordinary skill in the art will recognize that “at least part of the vaporized compound is deposited” means that some or all of the compound reacts with or adheres to the substrate.

The temperature of the reactor may be controlled by either controlling the temperature of the substrate holder or controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 100° C. to approximately 500° C. When a plasma deposition process is utilized, the deposition temperature may range from approximately 150° C. to approximately 400° C. Alternatively, when a thermal process is performed, the deposition temperature may range from approximately 200° C. to approximately 500° C.

In addition to the disclosed compound, a reactant may also be introduced into the reactor. The reactant may be an oxidizing gas such as one of O₂, O₃, H₂O, H₂O₂, NO, N₂O, NO₂, oxygen containing radicals such as O. or OH., NO, NO₂, carboxylic acids, formic acid, acetic acid, propionic acid, and mixtures thereof. Preferably, the oxidizing gas is selected from the group consisting of O₂, O₃, H₂O, H₂O₂, oxygen containing radicals thereof such as O. or OH., and mixtures thereof.

Alternatively, the reactant may be a reducing gas such as one of H₂, H₂CO, NH₃, SiH₄, Si₂H₆, Si₃H₈, (CH₃)₂SiH₂, (C₂H₅)₂SiH₂, (CH₃)SiH₃, (C₂H₅)SiH₃, phenyl silane, N₂H₄, N(SiH₃)₃, N(CH₃)H₂, N(C₂H₅)H₂, N(CH₃)₂H, N(C₂H₅)₂H, N(CH₃)₃, N(C₂H₅)₃, (SiMe₃)₂NH, (CH₃)HNNH₂, (CH₃)₂NNH₂, phenyl hydrazine, N-containing molecules, B₂H₆, 9-borabicyclo[3,3,1]nonane, dihydrobenzenfuran, pyrazoline, trimethylaluminium, dimethylzinc, diethylzinc, radical species thereof, and mixtures thereof. Preferably, the reducing as is H₂, NH₃, SiH₄, Si₂H₆, Si₃H₈, SiH₂Me₂, SiH₂Et₂, N(SiH₃)₃, hydrogen radicals thereof, or mixtures thereof.

The reactant may be treated by a plasma, in order to decompose the reactant into its radical form. N₂ may also be utilized as a reducing gas when treated with plasma. For instance, the plasma may be generated with a power ranging from about 50 W to about 500 W, preferably from about 100 W to about 400 W. The plasma may be generated or present within the reactor itself. Alternatively, the plasma may generally be at a location removed from the reactor, for instance, in a remotely located plasma system. One of skill in the art will recognize methods and apparatus suitable for such plasma treatment.

For example, the reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reactant using in-situ plasma is typically less than achieved using a remote plasma source for the same power input and is therefore not as efficient in reactant disassociation as a remote plasma system, which may be beneficial for the deposition of Group 4 transition metal-containing films on substrates easily damaged by plasma.

Alternatively, the plasma-treated reactant may be produced outside of the reaction chamber. The MKS Instruments' ASTRONi® reactive gas generator may be used to treat the reactant prior to passage into the reaction chamber. Operated at 2.45 GHz, 7 kW plasma power, and a pressure ranging from approximately 0.5 Torr to approximately 10 Torr, the reactant O₂ may be decomposed into two O. radicals. Preferably, the remote plasma may be generated with a power ranging from about 1 kW to about 10 kW, more preferably from about 2.5 kW to about 7.5 kW.

The vapor deposition conditions within the chamber allow the disclosed compound and the reactant to react and form a Group 4 transition metal-containing film on the substrate. In some embodiments, Applicants believe that plasma-treating the reactant may provide the reactant with the energy needed to react with the disclosed compound.

Depending on what type of film is desired to be deposited, an additional precursor compound may be introduced into the reactor. The precursor may be used to provide additional elements to the Group 4 transition metal-containing film. The additional elements may include lanthanides (Ytterbium, Erbium, Dysprosium, Gadolinium, Praseodymium, Cerium, Lanthanum, Yttrium), germanium, silicon, titanium, manganese, ruthenium, bismuth, lead, magnesium, aluminum, or mixtures of these. When an additional precursor compound is utilized, the resultant film deposited on the substrate contains the Group 4 transition metal in combination with at least one additional element.

The Group 4 transition metal-containing compounds and reactants may be introduced into the reactor either simultaneously (chemical vapor deposition), sequentially (atomic layer deposition) or different combinations thereof. The reactor may be purged with an inert gas between the introduction of the compound and the introduction of the reactant. Alternatively, the reactant and the compound may be mixed together to form a reactant/compound mixture, and then introduced to the reactor in mixture form. Another example is to introduce the reactant continuously and to introduce the at least one Group 4 transition metal-containing compound by pulse (pulsed chemical vapor deposition).

The vaporized compound and the reactant may be pulsed sequentially or simultaneously (e.g. pulsed CVD) into the reactor. Each pulse of compound may last for a time period ranging from about 0.01 seconds to about 10 seconds, alternatively from about 0.3 seconds to about 3 seconds, alternatively from about 0.5 seconds to about 2 seconds. In another embodiment, the reactant may also be pulsed into the reactor. In such embodiments, the pulse of each gas may last for a time period ranging from about 0.01 seconds to about 10 seconds, alternatively from about 0.3 seconds to about 3 seconds, alternatively from about 0.5 seconds to about 2 seconds. In another alternative, the vaporized compound and one or more reactants may be simultaneously sprayed from a shower head under which a susceptor holding several wafers is spun (spatial ALD).

Depending on the particular process parameters, deposition may take place for a varying length of time. Generally, deposition may be allowed to continue as long as desired or necessary to produce a film with the necessary properties. Typical film thicknesses may vary from several angstroms to several hundreds of microns, depending on the specific deposition process. The deposition process may also be performed as many times as necessary to obtain the desired film.

In one non-limiting exemplary CVD type process, the vapor phase of the disclosed Group 4 transition metal-containing compound and a reactant are simultaneously introduced into the reactor. The two react to form the resulting Group 4 transition metal-containing thin film. When the reactant in this exemplary CVD process is treated with a plasma, the exemplary CVD process becomes an exemplary PECVD process. The reactant may be treated with plasma prior or subsequent to introduction into the chamber.

In one non-limiting exemplary ALD type process, the vapor phase of the disclosed Group 4 transition metal-containing compound is introduced into the reactor, where it is contacted with a suitable substrate. Excess compound may then be removed from the reactor by purging and/or evacuating the reactor. A desired gas (for example, H₂) is introduced into the reactor where it reacts with the absorbed compound in a self-limiting manner. Any excess reducing gas is removed from the reactor by purging and/or evacuating the reactor. If the desired film is a Group 4 transition metal film, this two-step process may provide the desired film thickness or may be repeated until a film having the necessary thickness has been obtained.

Alternatively, if the desired film contains Group 4 transition metal and a second element, the two-step process above may be followed by introduction of the vapor of an additional precursor compound into the reactor. The additional precursor compound will be selected based on the nature of the Group 4 transition metal film being deposited. After introduction into the reactor, the additional precursor compound is contacted with the substrate. Any excess precursor compound is removed from the reactor by purging and/or evacuating the reactor. Once again, a desired gas may be introduced into the reactor to react with the precursor compound. Excess gas is removed from the reactor by purging and/or evacuating the reactor. If a desired film thickness has been achieved, the process may be terminated. However, if a thicker film is desired, the entire four-step process may be repeated. By alternating the provision of the Group 4 transition metal-containing compound, additional precursor compound, and reactant, a film of desired composition and thickness can be deposited.

When the reactant in this exemplary ALD process is treated with a plasma, the exemplary ALD process becomes an exemplary PEALD process. The reactant may be treated with plasma prior or subsequent to introduction into the chamber.

In a second non-limiting exemplary ALD type process, the vapor phase of one of the disclosed Zr-containing precursor, for example methylcyclopentadienyl (N,N-bis(tert-butyl)ethene-1,2-diaminato) mono(iso-propylalkoxo) Zirconium(Zr), is introduced into the reactor, where it is contacted with the TiN substrate. Excess Zr-containing precursor may then be removed from the reactor by purging and/or evacuating the reactor. A desired gas (for example, O₃) is introduced into the reactor where it reacts with the absorbed Zr-containing precursor in a self-limiting manner to form a ZrO₂ film. Any excess oxidizing gas is removed from the reactor by purging and/or evacuating the reactor. These two steps may be repeated until the ZrO₂ film obtains a desired thickness. The resulting TiN/ZrO₂/TiN stack may be used in DRAM capacitors.

The Group 4 transition metal-containing films resulting from the processes discussed above may include a pure Group 4 transition metal (M=Ti, Zr, Hf), Group 4 transition metal silicide (MₖSiₗ), or Group 4 transition metal oxide (MₙOₘ), Group 4 transition metal nitride (M₀Nₚ) film wherein k, l, m, n, o and p are integers which inclusively range from 1 to 6. One of ordinary skill in the art will recognize that by judicial selection of the appropriate disclosed compound, optional precursor compounds, and reactant species, the desired film composition may be obtained.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the Group 4 transition metal-containing film may be exposed to a temperature ranging from approximately 200° C. and approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Group 4 transition metal-containing film. This in turn tends to improve the resistivity of the film.

### EXAMPLES

The following examples illustrate experiments performed in conjunction with the disclosure herein. The examples are not intended to be all inclusive and are not intended to limit the scope of disclosure described herein.

### Example 1

### cyclopentadienyl (N,N-bis(tert-butyl)ethene-1,2-diaminato) (iso-propylalkoxo) Zirconium(IV) synthesis

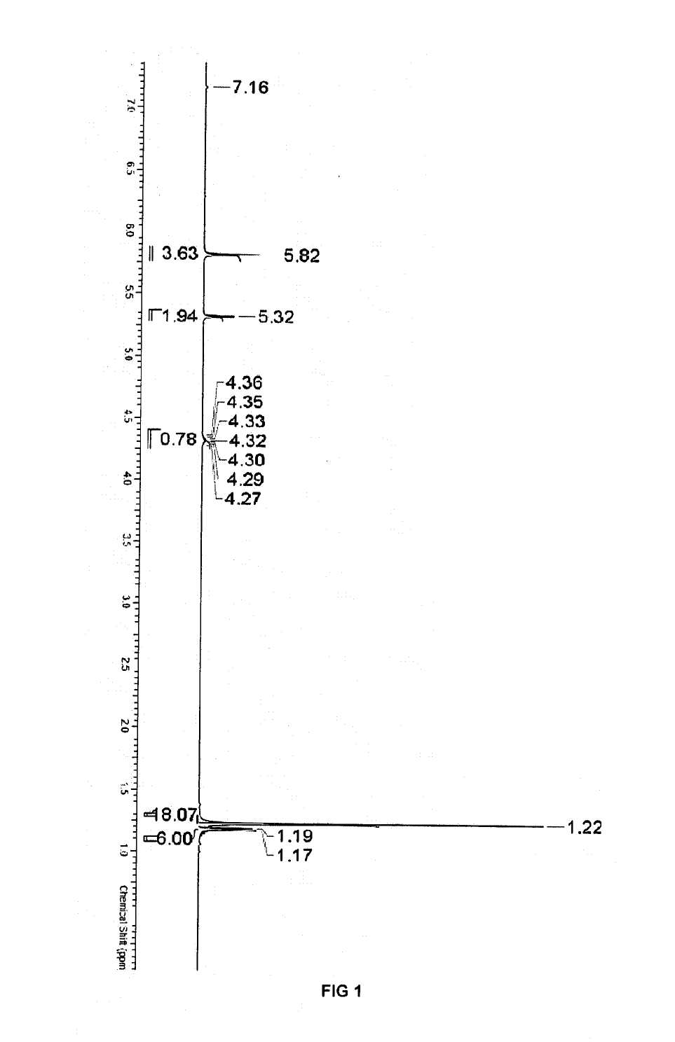

To a solution of Zr(Cp)(Cl)₃ (92.1 g, 0.35 mol) in ca. 200 mL of tetrahydrofuran (THF) at −78° C., was added dropwise a freshly prepared solution of Li₂(tBuDAD) (0.35 mol) in THF. The mixture was slowly warmed to room temperature and stirred overnight. The mixture was cooled to −78° C., and a solution of Li(OiPr) (23.1 g, 0.35 mol) in THF was added dropwise. The mixture was slowly warmed to room temperature and stirred overnight. Solvent was then removed under vacuum to give a dark red oil. The material was extracted in pentane and then purified by distillation at 150° C. @ 250 mTorr (bp˜102-109° C.) to give 81.1 g (60%) of a pure red oil. The NMR¹H spectrum is provided in FIG. 1. NMR¹H (δ, ppm, C6D6): 5.81 (s, 4H), 5.31 (s, 2H), 4.31 (m, 1H), 1.22 (s, 18H), 1.17 (d, 6H).

The oil left a 3.2% residual mass during TGA analysis measured at a temperature rising rate of 10° C./min in an atmosphere which flows nitrogen at 200 mL/min. These results are shown in FIG. 5, which is a TGA graph illustrating the percentage of weight loss upon temperature increase.

### Example 2

### cyclopentadienyl (N,N-bis(tert-butyl)ethene-1,2-diaminato) (tert-butylalkoxo) Zirconium(IV) synthesis

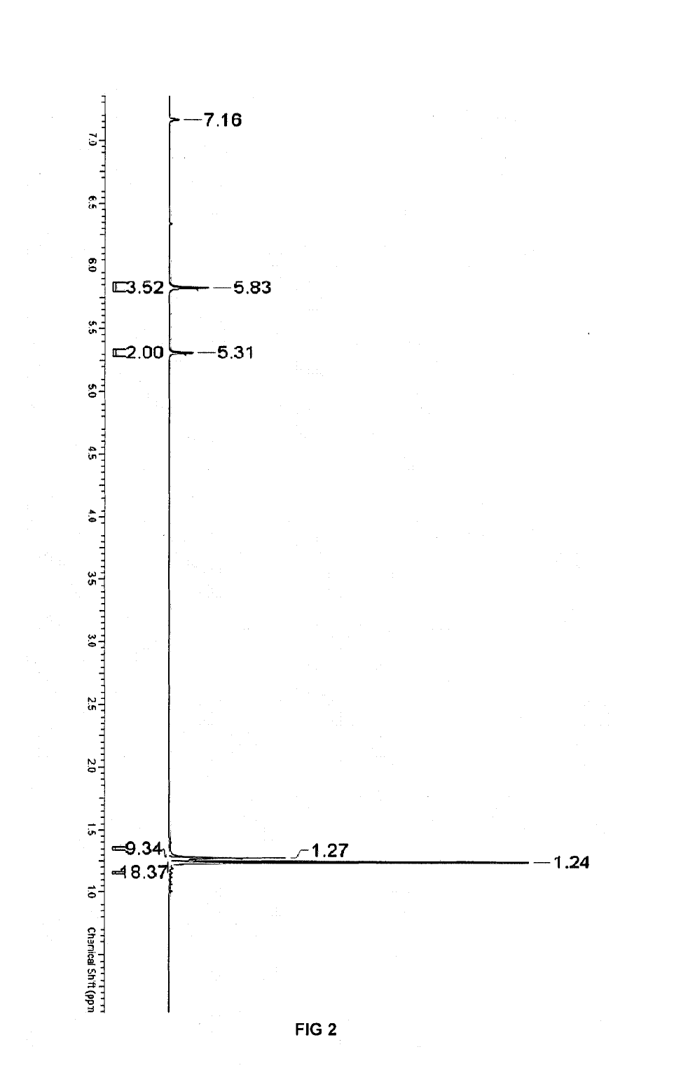

To a solution of Zr(Cp)(tBuDAD)(NMe₂) (1.28 g, 3.5 mmol) in ca. 20 mL of tetrahydrofuran (THF) at −78° C., was added dropwise a freshly prepared solution of tBuOH (0.26 g, 3.5 mmol) in THF. The mixture was slowly warmed to room temperature and stirred overnight. Solvent was then removed under vacuum to give a yellow solid. The material was purified by sublimation at 100° C. @ 8 mTorr to give 1.00 g (72%) of a pure yellow solid. The NMR¹H spectrum is provided in FIG. 2. NMR¹H (δ, ppm, C6D6): 5.83 (s, 4H), 5.31 (s, 2H), 1.27 (s, 9H), 1.24 (m, 18H)

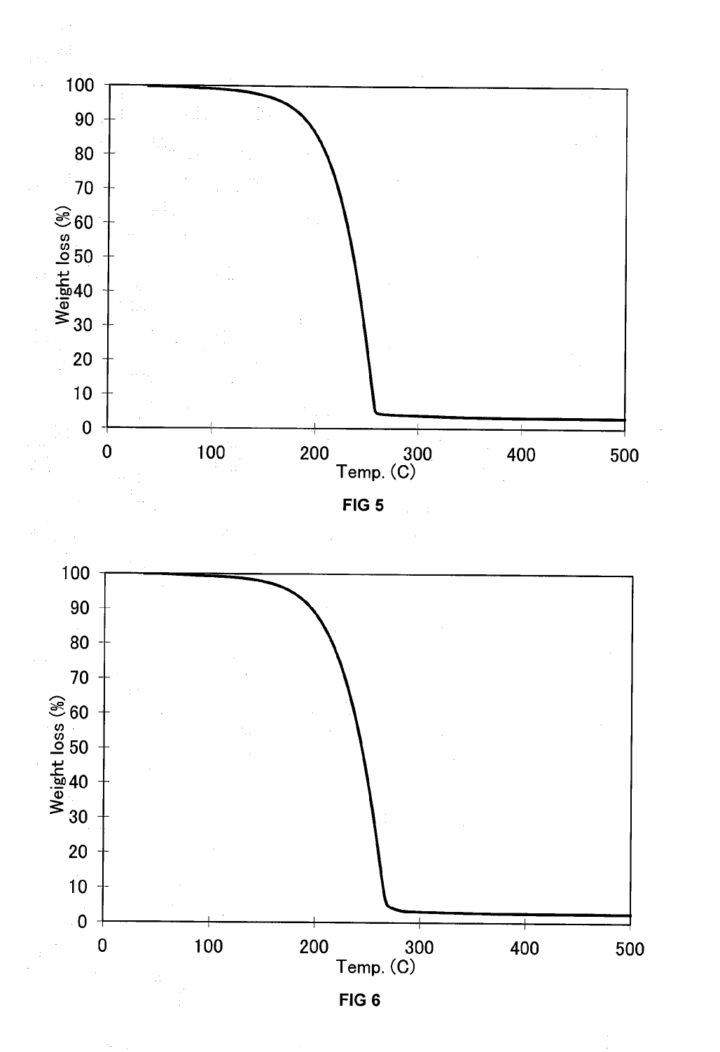

The solid left a 2.5% residual mass during TGA analysis measured at a temperature rising rate of 10° C./min in an atmosphere which flows nitrogen at 200 mL/min. These results are shown in FIG. 6, which is a TGA graph illustrating the percentage of weight loss upon temperature increase.

### Example 3

### cyclopentadienyl (N,N-bis(tert-butyl)ethene-1,2-diaminato) (ethylalkoxo) Zirconium(IV) synthesis

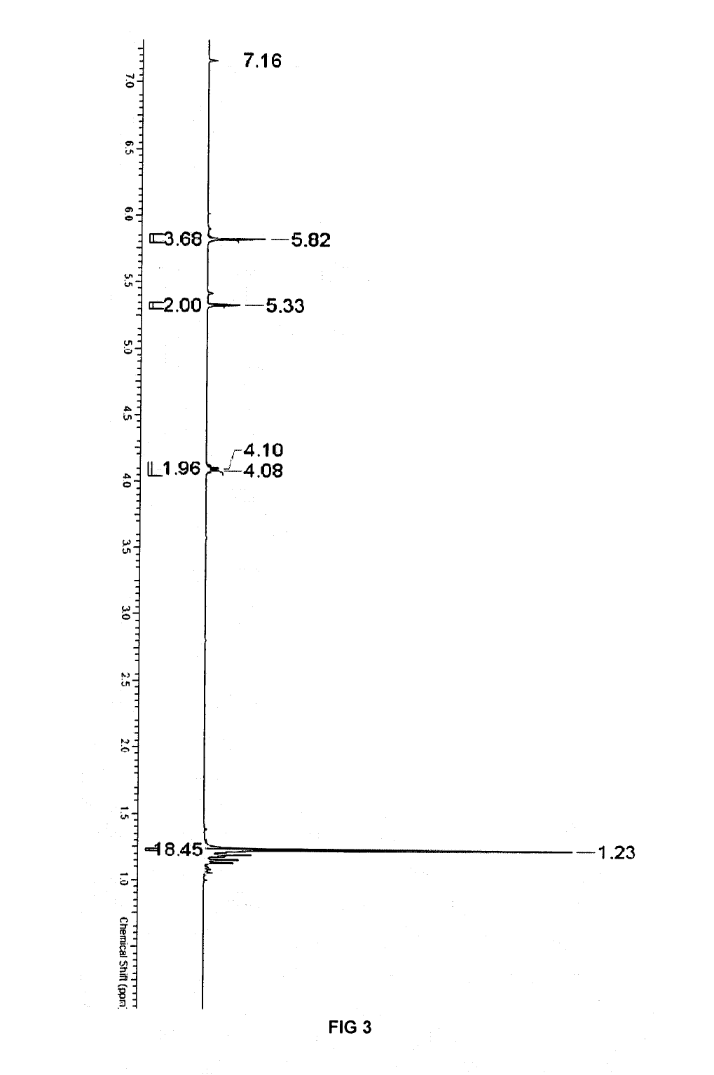

To a solution of Zr(Cp)(Cl)₃ (2.0 g, 7.6 mmol) in ca. 20 mL of tetrahydrofuran (THF) at −78° C., was added dropwise a freshly prepared solution of Li₂(tBuDAD) (7.6 mmol) in THF. The mixture was slowly warmed to room temperature and stirred overnight. The mixture was cooled to −78° C. and a solution of Na(OEt) (0.52 g, 7.6 mmol) in THF was added dropwise. The mixture was slowly warmed to room temperature and stirred overnight. Solvent was then removed under vacuum to give a yellow solid. The material was extracted in pentane and then purified by distillation at 170° C. @ 6 mTorr (bp˜74-84° C.) to give 0.75 g (27%) of a pure yellow solid. The NMR¹H spectrum is provided in FIG. 3. NMR¹H (δ, ppm, C6D6): 5.82 (s, 4H), 5.33 (s, 2H), 4.09 (q, 2H), 1.23 (s, 18H), 1.19 (t, 3H).

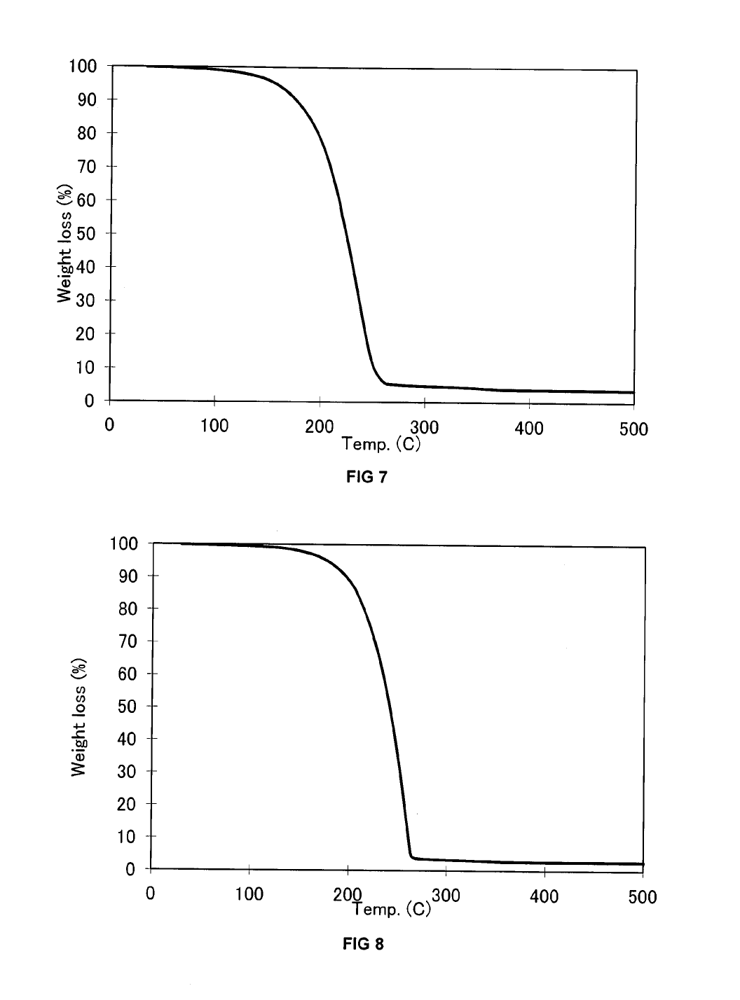

The solid left a 3.7% residual mass during TGA analysis measured at a temperature rising rate of 10° C./min in an atmosphere which flows nitrogen at 200 mL/min. These results are shown in FIG. 7, which is a TGA graph illustrating the percentage of weight loss upon temperature increase.

### Example 4

### methylcyclopentadienyl (N,N-bis(tert-butyl)ethene-1,2-diaminato) (iso-propylalkoxo) Zirconium(IV) synthesis

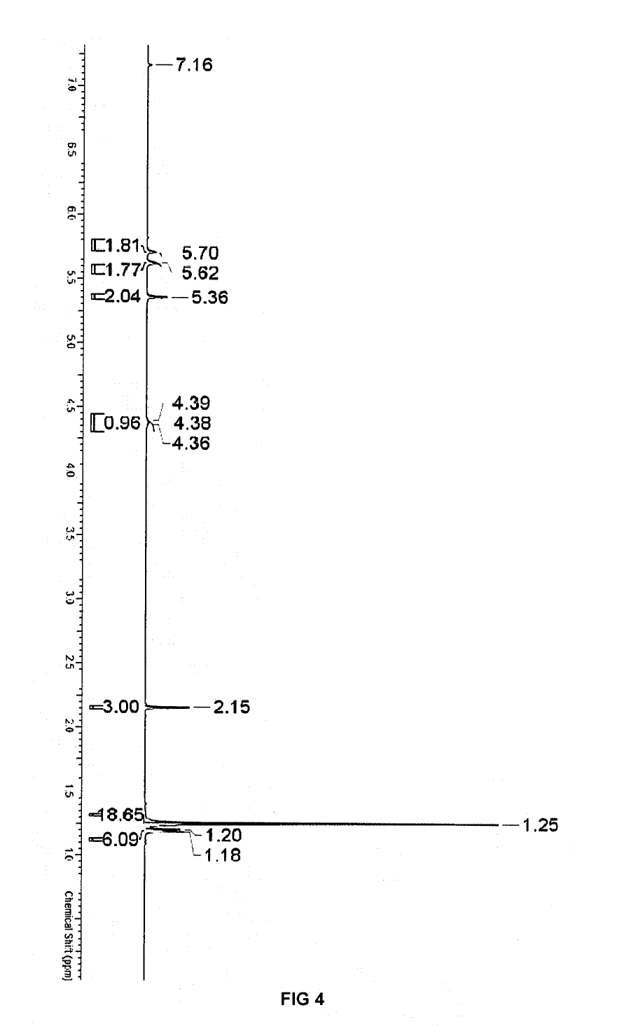

To a solution of Zr(MeCp)(Cl)₃ (51.64 g, 0.187 mol) in ca. 100 mL of tetrahydrofuran (THF) at −78° C., was added dropwise a freshly prepared solution of Li₂(tBuDAD) (0.187 mol) in THF. The mixture was slowly warmed to room temperature and stirred overnight. The mixture was cooled to −78° C., and a solution of Li(OiPr) (12.32 g, 0.187 mol) in THF was added dropwise. The mixture was slowly warmed to room temperature and stirred overnight. Solvent was then removed under vacuum to give a dark red oil. The material was extracted in pentane and then purified by distillation @ 250 mTorr at 150° C. (head temperature) to give 47.9 g (71%) of a pure orange-red oil. The NMR¹H spectrum is provided in FIG. 4. NMR¹H (δ, ppm, C6D6): 5.62-5.70 (m, 4H), 5.36 (s, 2H), 4.38 (m, 1H), 2.15 (s, 3H), 1.25 (s, 18H), 1.19 (d, 6H).

The oil left a 2.6% residual mass during TGA analysis measured at a temperature rising rate of 10° C./min in an atmosphere which flows nitrogen at 200 mL/min. These results are shown in FIG. 8, which is a TGA graph illustrating the percentage of weight loss upon temperature increase.

### Example 5

### ALD of cyclopentadienyl (N,N-bis(tert-butyl)ethene-1,2-diaminato)(isopropoxyalkoxo) Zirconium(IV)

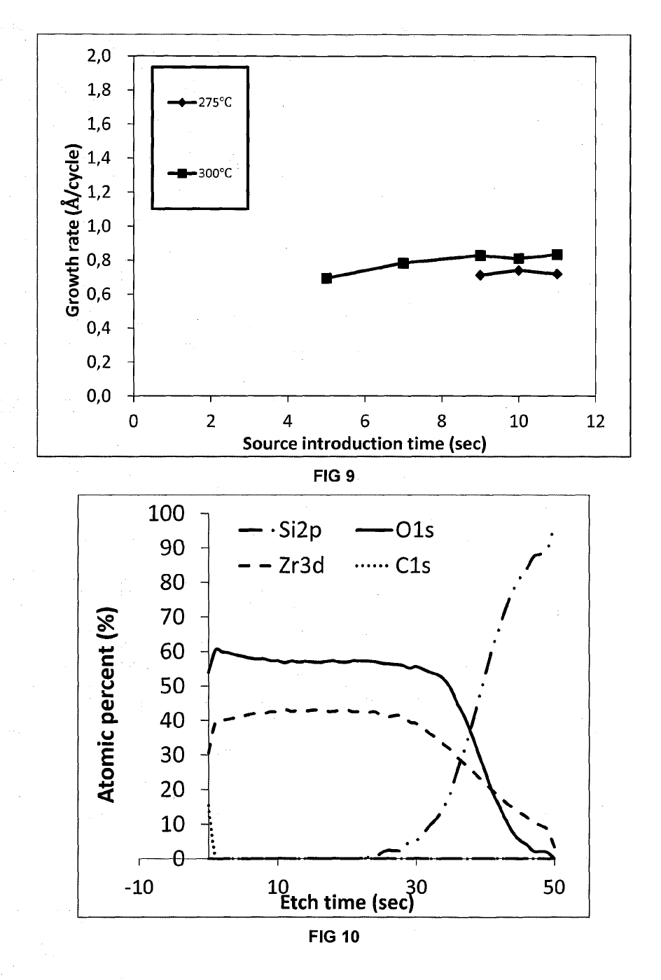

ALD tests were performed using the cyclopentadienyl (N,N-bis(tert-butyl)ethene-1,2-diaminato)(iso-propylalkoxo) Zirconium(IV) prepared in Example 1, which was be placed in a vessel heated up to 60° C. and O₃ as oxidizing reactant. Typical ALD conditions were used with a reactor pressure fixed at ˜0.5 Torr. ALD behavior with complete surface saturation and reaction was assessed in a temperature window of 275-300° C. on pure silicon wafers. The growth rates in ALD window were in the range 0.6-1.0 Å/cycle. FIG. 9 shows the growth rates of ZrO₂ thin films using cyclopentadienyl (N,N-bis(tert-butyl)ethene-1,2-diaminato) (iso-propylalkoxo) Zirconium(IV)/O₃ as a function of the source introduction time between 275-300° C. FIG. 10 shows the X-ray Photoelectron Spectroscopy (XPS) of ZrO₂ film growth using cyclopentadienyl (N,N-bis(tert-butyl)ethene-1,2-diaminato)(iso-propylalkoxo) Zirconium(IV) and shows that all impurities are below the detection limit of the analytic tool (<1%). FIG. 11 shows the X-rays diffraction spectrum of a ZrO₂ film growth using cyclopentadienyl (N,N-bis(tert-butyl)ethene-1,2-diaminato)(iso-propylalkoxo) Zirconium(IV) at 300° C. and shows that the film grown in this condition is purely cubic/tetragonal.

### Example 6

### ALD of methylcyclopentadienyl (N,N-bis(tert-butyl)ethene-1,2-diaminato)(isopropoxyalkoxo) Zirconium(IV)

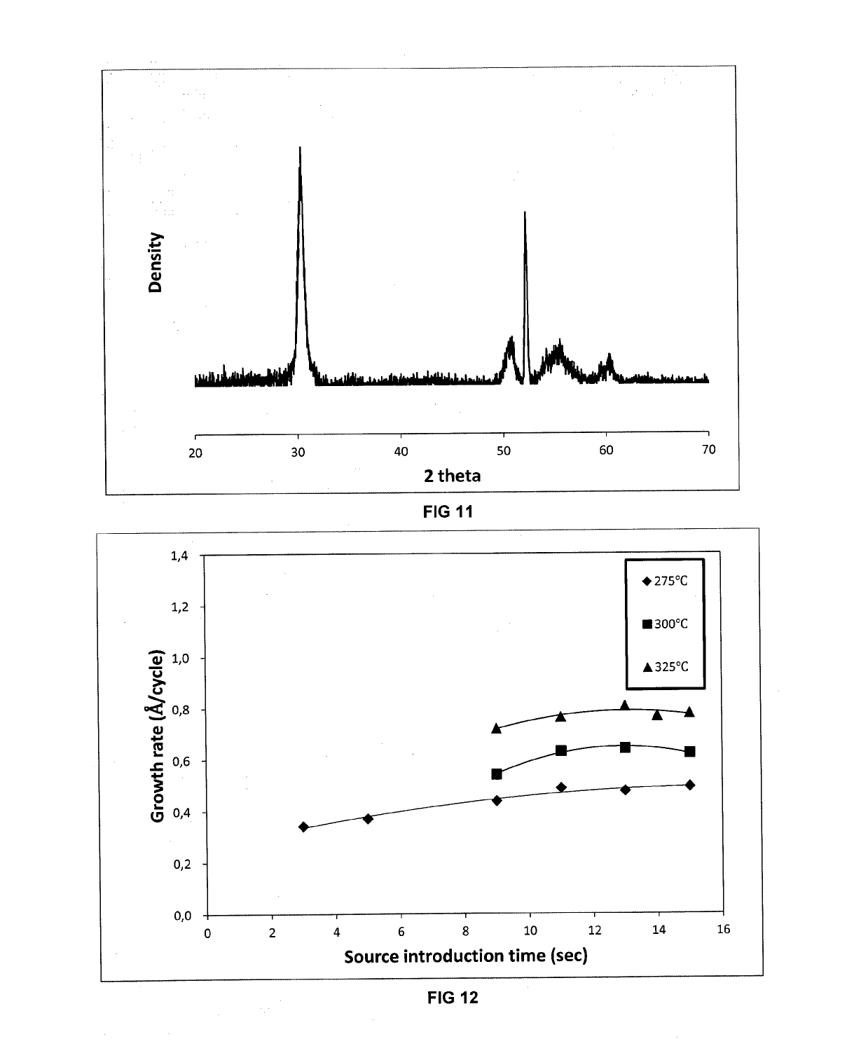

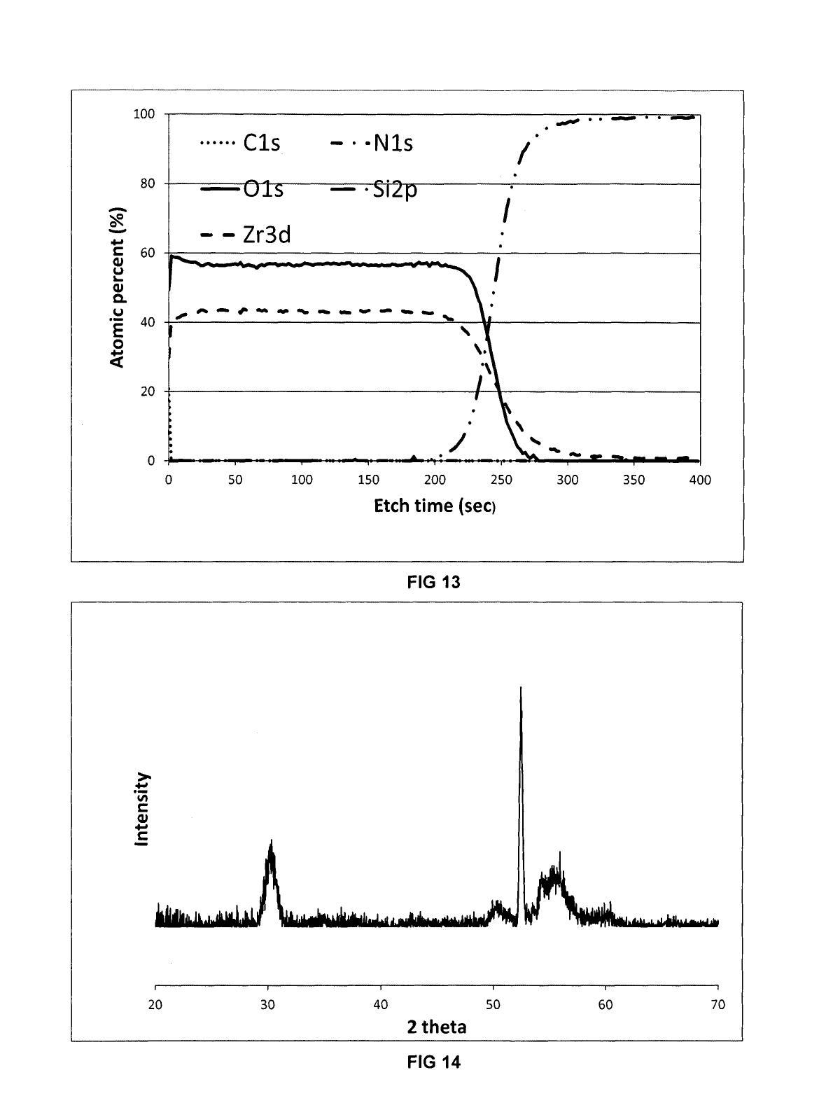

ALD tests were performed using the methylcyclopentadienyl (N,N-bis(tert-butyl)ethene-1,2-diaminato)(iso-propylalkoxo) Zirconium(IV) prepared in Example 4, which was be placed in a vessel heated up to 75° C. and O₃ as oxidizing reactant. Typical ALD conditions were used with a reactor pressure fixed at −0.5 Torr. ALD behavior with complete surface saturation and reaction was assessed in a temperature window of 275-325° C. on pure silicon wafers. The growth rates in ALD window were in the range 0.3-1.0 Å/cycle. FIG. 12 shows the growth rates of ZrO₂ thin films using methylcyclopentadienyl (N,N-bis(tert-butyl)ethene-1,2-diaminato) (iso-propylalkoxo) Zirconium(IV)/O₃ as a function of the source introduction time between 275-325° C. FIG. 13 shows the X-ray Photoelectron Spectroscopy (XPS) of ZrO₂ film growth using methylcyclopentadienyl (N,N-bis(tert-butyl)ethene-1,2-diaminato)(iso-propylalkoxo) Zirconium(IV) and shows that all impurities are below the detection limit of the analytic tool (<1%). FIG. 14 shows the X-rays diffraction spectrum of a ZrO₂ film growth using methylcyclopentadienyl (N,N-bis(tert-butyl)ethene-1,2-diaminato)(iso-propylalkoxo) Zirconium(IV) at 325° C. and shows that the film grown in this condition is purely cubic/tetragonal.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

We claim:

1. A Group 4 transition metal-containing thin film forming precursor having the following formula: 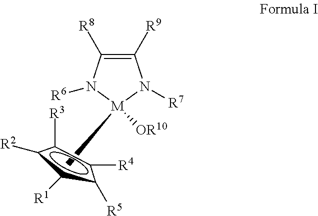
wherein M is selected from a Group 4 transition metal consisting of Ti, Zr, or Hf and each R¹, R², R³, R⁴, R⁵, R⁶, R⁷, R⁸, R⁹, and R¹⁰ is independently selected from H; a C1-C5 linear, branched, or cyclic alkyl group; a C1-C5 linear, branched, or cyclic alkylsilyl group; a C1-C5 linear, branched, or cyclic alkylamino group; or a C1-C5 linear, branched, or cyclic fluoroalkyl group.

2. The Group 4 transition metal-containing thin film forming precursor of claim 1, wherein the precursor is selected from the group consisting of:
cyclopentadienyl(N,N-bis(tert-butyl)ethene-1,2-diaminato) (tert-butylalkoxo) Titanium(IV);
cyclopentadienyl(N,N-bis(tert-butyl)ethene-1,2-diaminato) (sec-butylalkoxo) Titanium(IV);
cyclopentadienyl(N,N-bis(tert-butyl)ethene-1,2-diaminato) (n-butylalkoxo) Titanium(IV);
cyclopentadienyl(N,N-bis(tert-butyl)ethene-1,2-diaminato) (i-butylalkoxo) Titanium(IV);
cyclopentadienyl(N,N-bis(tert-butyl)ethene-1,2-diaminato) (iso-propylalkoxo) Titanium(IV);
cyclopentadienyl(N,N-bis(tert-butyl)ethene-1,2-diaminato) (n-propylalkoxo) Titanium(IV);
cyclopentadienyl(N,N-bis(tert-butyl)ethene-1,2-diaminato) (ethylalkoxo) Titanium(IV);
cyclopentadienyl(N,N-bis(tert-butyl)ethene-1,2-diaminato) (methylalkoxo) Titanium(IV);
methylcyclopentadienyl(N,N-bis(tert-butyl)ethene-1,2-diaminato) (iso-propylalkoxo) Titanium(IV);
pentamethylcyclopentadienyl(N,N-bis(tert-butyl)ethene-1,2-diaminato) (iso-propylalkoxo) Titanium(IV);
cyclopentadienyl(N,N-bis(iso-propyl)ethene-1,2-diaminato) (iso-propylalkoxo) Titanium(IV);
(trimethylsilyl-cyclopentadienyl)(N,N-bis(tert-butyl)ethene-1,2-diaminato) (iso-propylalkoxo) Titanium(IV);
(trimethylsilyl-cyclopentadienyl)(N,N-bis(tert-butyl)ethene-1,2-diaminato) (iso-propylalkoxo) Titanium(IV);
(2, 3, 4, 5-tetramethyl-trifluoromethylcyclopentadienyl)(N,N-bis(tert-butyl)ethene-1,2-diaminato)(iso-propylalkoxo) Titanium(IV);
(cyclopentadienyl)(N,N-bis(tert-butyl)ethene-1,2-diaminato)(diethyihydroxylamine) Titanium(IV);
cyclopentadienyl(N,N-bis(tert-butyl)ethene-1,2-diaminato) (tert-butylalkoxo) Zirconium(IV);
cyclopentadienyl(N,N-bis(tert-butyl)ethene-1,2-diaminato) (sec-butylalkoxo) Zirconium(IV);
cyclopentadienyl(N,N-bis(tert-butyl)ethene-1,2-diaminato) (n-butylalkoxo) Zirconium(IV);
cyclopentadienyl(N,N-bis(tert-butyl)ethene-1,2-diaminato) (i-butylalkoxo) Zirconium(IV);
cyclopentadienyl(N,N-bis(tert-butyl)ethene-1,2-diaminato) (iso-propylalkoxo) Zirconium(IV);
cyclopentadienyl(N,N-bis(tert-butyl)ethene-1,2-diaminato) (n-propylalkoxo) Zirconium(IV);
cyclopentadienyl(N,N-bis(tert-butyl)ethene-1,2-diaminato) (ethylalkoxo) Zirconium(IV);
cyclopentadienyl(N,N-bis(tert-butyl)ethene-1,2-diaminato) (methylalkoxo) Zirconium(IV);
methylcyclopentadienyl(N,N-bis(tert-butyl)ethene-1,2-diaminato) (iso-propylalkoxo) Zirconium(IV);
pentamethylcyclopentadienyl(N,N-bis(tert-butyl)ethene-1,2-diaminato) (iso-propylalkoxo) Zirconium(IV);
cyclopentadienyl(N,N-bis(iso-propyl)ethene-1,2-diaminato) (iso-propylalkoxo) Zirconium (IV);
(trimethylsilyl-cyclopentadienyl)(N,N-bis(tert-butyl)ethene-1,2-diaminato) (iso-propylalkoxo) Zirconium (IV);
(trimethylsilyl-cyclopentadienyl)(N,N-bis(tert-butyl)ethene-1,2-diaminato) (iso-propylalkoxo) Zirconium (IV);
(2, 3, 4, 5-tetramethyl-trifluoromethylcyclopentadienyl)(N,N-bis(tert-butyl)ethene-1,2-diaminato)(iso-propylalkoxo) Zirconium (IV);
(cyclopentadienyl)(N,N-bis(tert-butyl)ethene-1,2-diaminato) (diethyihydroxylamine) Zirconium (IV);
cyclopentadienyl(N,N-bis(tert-butyl)ethene-1,2-diaminato) (tert-butylalkoxo) Hafnium(IV);
cyclopentadienyl(N,N-bis(tert-butyl)ethene-1,2-diaminato) (sec-butylalkoxo) Hafnium(IV);
cyclopentadienyl(N,N-bis(tert-butyl)ethene-1,2-diaminato) (n-butylalkoxo) Hafnium(IV);
cyclopentadienyl(N,N-bis(tert-butyl)ethene-1,2-diaminato) (i-butylalkoxo) Hafnium(IV);
cyclopentadienyl(N,N-bis(tert-butyl)ethene-1,2-diaminato) (iso-propylalkoxo) Hafnium(IV);
cyclopentadienyl(N,N-bis(tert-butyl)ethene-1,2-diaminato) (n-propylalkoxo) Hafnium(IV);
cyclopentadienyl(N,N-bis(tert-butyl)ethene-1,2-diaminato) (ethylalkoxo) Hafnium(IV);
cyclopentadienyl(N,N-bis(tert-butyl)ethene-1,2-diaminato) (methylalkoxo) Hafnium(IV);
methylcyclopentadienyl(N,N-bis(tert-butyl)ethene-1,2-diaminato)\ (iso-propylalkoxo) Hafnium(IV);
pentamethylcyclopentadienyl(N,N-bis(tert-butyl)ethene-1,2-diaminato) (iso-propylalkoxo) Hafnium(IV);
cyclopentadienyl(N,N-bis(iso-propyl)ethene-1,2-diaminato) (iso-propylalkoxo) Hafnium(IV);
(trimethylsilyl-cyclopentadienyl)(N,N-bis(tert-butyl)ethene-1,2-diaminato) (iso-propylalkoxo) Hafnium (IV);
(trimethylsilyl-cyclopentadienyl)(N,N-bis(tert-butyl)ethene-1,2-diaminato) (iso-propylalkoxo) Hafnium (IV);
(2, 3, 4, 5-tetramethyl-trifluoromethylcyclopentadienyl)(N,N-bis(tert-butyl)ethene-1,2-diaminato)(iso-propylalkoxo) Hafnium (IV); and
(cyclopentadienyl)(N,N-bis(tert-butyl)ethene-1,2-diaminato)(diethylhydroxylamine) Hafnium (IV).

3. The Group 4 transition metal-containing thin film forming precursor of claim 2, wherein the precursor is cyclopentadienyl (N,N-bis(tert-butyl)ethene-1,2-diaminato)(iso-propylalkoxo) Titanium(IV), methylcyclopentadienyl (N,N-bis(tert-butyl)ethene-1,2-diaminato)(iso-propylalkoxo) Titanium(IV), cyclopentadienyl (N,N-bis(tert-butyl)ethene-1,2-diaminato)(ethylalkoxo) Titanium(IV), or cyclopentadienyl (N,N-bis(tert-butyl)ethene-1,2-diaminato)(methylalkoxo) Titanium(IV).

4. The Group 4 transition metal-containing thin film forming precursor of claim 2, wherein the precursor is cyclopentadienyl (N,N-bis(tert-butyl)ethene-1,2-diaminato)(iso-propylalkoxo) Zirconium(IV), methylcyclopentadienyl (N,N-bis(tert-butyl)ethene-1,2-diaminato)(iso-propylalkoxo) Zirconium(IV), cyclopentadienyl (N,N-bis(tert-butyl)ethene-1,2-diaminato)(ethylalkoxo) Zirconium(IV), or cyclopentadienyl (N,N-bis(tert-butyl)ethene-1,2-diaminato)(methylalkoxo) Zirconium(IV).

5. The Group 4 transition metal-containing thin film forming precursor of claim 2, wherein the precursor is cyclopentadienyl (N,N-bis(tert-butyl)ethene-1,2-diaminato)(iso-propylalkoxo) Hafnium(IV), methylcyclopentadienyl (N,N-bis(tert-butyl)ethene-1,2-diaminato)(iso-propylalkoxo) Hafnium(IV), cyclopentadienyl (N,N-bis(tert-butyl)ethene-1,2-diaminato)(ethylalkoxo) Hafnium(IV), or cyclopentadienyl (N,N-bis(tert-butyl)ethene-1,2-diaminato)(methylalkoxo) Hafnium(IV).

6. A method of depositing of a Group 4 transition metal-containing film on a substrate, comprising the steps of: introducing a vapor of the Group 4 transition metal-containing thin film forming precursor of claim 1 into a reactor having a substrate disposed therein and depositing at least part of the Group 4 transition metal-containing thin film forming precursor onto the substrate.

7. The method of claim 6, further comprising introducing at least one reactant into the reactor.

8. The method of claim 7, wherein the reactant is selected from the group consisting of H₂, H₂CO N₂H₄, NH₃, SiH₄, Si₂H₆, Si₃H₈, SiH₂Me₂, SiH₂Et₂, N(SiH₃)₃, hydrogen radicals thereof, and mixtures thereof.

9. The method of claim 7, wherein the reactant is selected from the group consisting of: O₂, O₃, H₂O, H₂O₂, NO, N₂O, NO₂, oxygen radicals thereof, and mixtures thereof.

10. The method of claim 7, wherein the Group 4 transition metal-containing thin film forming precursor and the reactant are introduced into the reactor simultaneously and the reactor is configured for chemical vapor deposition.

11. The method of claim 7 wherein the Group 4 transition metal-containing thin film forming precursor and the reactant are introduced into the chamber sequentially and the reactor is configured for atomic layer deposition.

12. The method of claim 7, wherein the substrate is TiN and the precursor is used to form a DRAM capacitor

13. The method of claim 10, wherein the deposition is plasma enhanced.

14. The method of claim 11, wherein the deposition is plasma enhanced.
